(19) United States
(12) Patent Application Publication
(10) Pub. No.: US 2026/0196921 A1
(43) Pub. Date: Jul. 9, 2026

(54) DEVICE FOR CONTROLLING A THREE-ELECTRODES POWER SWITCH

(71) Applicant: STMicroelectronics International N.V., Geneva (CH)

(72) Inventor: Ghafour BENABDELAZIZ, Tours (FR)

(21) Appl. No.: 19/439,080

(22) Filed: Jan. 2, 2026

(30) Foreign Application Priority Data
Jan. 9, 2025 (FR) 25/00185

(51) Int. Cl. H02M 1/08; H02M 1/00; H02M 1/36; H02M 3/335

(52) U.S. Cl. CPC H02M 1/08; H02M 1/0009; H02M 1/36; H02M 3/33576

(57) ABSTRACT

The present disclosure relates to a control device of a power switch with three-electrodes, comprising: a sensing circuit comprising bipolar transistors coupled to a first power electrode the power switch, and configured to extract a sensing current, the value of which is proportional to that of a voltage between the first and a second power electrodes of the power switch when the power switch is OFF; and a starting circuit, coupled to a control electrode of the power switch and to the sensing circuit, and configured to supply a non-zero starting current on the control electrode when the sensing current is zero and a non-zero starting control signal is received at a control input of the starting circuit.

### CROSS REFERENCE TO RELATED APPLICATIONS

This application claims the priority benefit of French Patent Application Number 25/00185, filed on Jan. 9, 2025, entitled “DISPOSITIF DE COMMANDE DE COMMUTATEUR DE PUISSANCE A TROIS ELECTRODES”, which is hereby incorporated by reference to the maximum extent allowable by law.

### TECHNICAL FIELD

The present description relates generally to the field of controlling three-electrodes power switch, especially TRIAC (Triode for Alternating Current), or thyristor, or SCR (Silicon Controlled Rectifier).

### BACKGROUND

Controlling a three-electrodes power switch, such as TRIAC or a thyristor, could request providing an electrical insulation between the control circuit and power switch, for example to form a security insulation intended to insulate the low voltage part from the high voltage part, or in the case of a control reference of the circuit control which is not identical to that of the power switch.

In addition, it could be appropriate to control the starting of the power switch when the value of the AC voltage applied on its terminals is zero in order to reduce the inrush currents which could flow through the power switch as well as the resulting constraints, and avoid a possible damage of the elements coupled to the power switch (battery, charger, lighting control, resistive load, etc.). Such a starting control with a zero-voltage value is referred to as ZVS (“Zero Voltage Switching”).

A first configuration to perform such a ZVS control of a power switch means using an opto-TRIAC with integrated ZVS, coupled between one of the power electrodes and the control electrode (the gate in the case of a TRIAC or a thyristor) of the power switch to be controlled. A control signal for starting the power switch is sent to the opto-TRIAC by a control circuit corresponding, for example, to a microcontroller. In this first configuration, electrical insulation between the control part and the power part is performed by the opto-TRIAC.

This first configuration allows automatically detecting the crossing by a zero value of the AC voltage across the power switch in order to trigger its starting thanks, on receipt of the starting control signal, to the opto-TRIAC with integrated ZVS could trigger the starting of the power switch only upon crossing a zero value of the AC voltage across the power switch. However, this first configuration has the drawback that there is a long delay between the time where the starting control signal is sent to the opto-TRIAC and the time where the power switch starts-up and turns ON, resulting in electromagnetic interference within the power circuit comprising the power switch. In addition, as the power switch is a TRIAC, this solution could be used only for a starting performed in the quadrants Q1 and Q3 (Q1: positive voltage across the TRIAC and positive gate current; Q3: negative voltage across the TRIAC and negative gate current).

A second configuration for performing such a ZVS control of the power switch means using an opto-transistor parallelly coupled with respect to the power switch to be controlled or connected to the AC line voltage (between line and neutral), a pulse transformer coupled to the control electrode of the power switch and a control circuit, for example, corresponding to a microcontroller. In this second configuration, electrical insulation between the control part and the power part is performed by the pulse transformer. When the AC voltage across the power switch crosses a zero value, the latter is detected by the opto-transistor which sends a signal to the microcontroller informing the same of the zero-value crossing. A control signal for starting the power switch is then sent from the microcontroller on the gate of the power switch via the pulse transformer.

Unlike the first configuration requiring an opto-TRIAC to perform an automatic ZVS control, synchronizing starting the power switch on the zero-value crossing of the AC voltage across its terminals is performed, in the second configuration, by the microcontroller and is thus not automatic. Further, the circuit comprising the opto-transistor forms an additional outer circuit to be connected to the power circuit to which the power switch belongs.

### BRIEF SUMMARY

There is a need to provide a device for controlling at least one three-electrodes power switch, such as a TRIAC or thyristor, having not at least part of the drawbacks of the existing solutions.

One embodiment overcomes some or all drawbacks of known solutions and provides a control device of at least one power switch with three-electrodes, comprising at least: a sensing circuit comprising bipolar transistors coupled to a first power electrode of the power switch, and configured to extract a sensing current, the value of which is proportional to that of a voltage between the first and a second power electrodes of the power switch when the power switch is OFF; and a starting circuit, coupled to a control electrode of the power switch and to the sensing circuit, and configured to supply a non-zero starting current on the control electrode when the sensing current is zero and a non-zero starting control signal is received at a control input of the starting circuit.

According to a particular embodiment, the sensing circuit is configured to cause the sensing current flowing from one to the another first and a second electrodes of the power switch when the power switch is OFF.

According to a particular embodiment, the control device is configured to control the power switch, corresponding to a TRIAC, the control electrode corresponding to a gate of the TRIAC, and the power electrodes corresponding to the anodes of the TRIAC.

According to a particular embodiment, the bipolar transistors of the sensing circuit correspond at least to: a first bipolar transistor of NPN type having its base coupled to the first power electrode of the power switch, its collector coupled to the control input of the starting circuit, and its emitter coupled to the second power electrode of the power switch; a second bipolar transistor of NPN type having its base coupled to the emitter of the first bipolar transistor, and its emitter coupled to the base of the first bipolar transistor;
and a third bipolar transistor of PNP type having its base coupled to the collector of the second bipolar transistor, its emitter coupled to the collector of the first bipolar transistor, and its collector coupled to the second power electrode of the power switch.

According to a particular embodiment, the starting circuit includes a fourth bipolar transistor of NPN type having its base coupled to the collector of the first bipolar transistor, its collector coupled to the control input of the starting circuit, and its emitter coupled to the control electrode of the power switch, or a MOSFET transistor having its gate coupled to collector of the first bipolar transistor, a first source or drain electrode coupled to the control input of the starting circuit, and a second source or drain electrode coupled to the control electrode of the power switch.

According to a particular embodiment, the bipolar transistors of the sensing circuit correspond at least to: a first bipolar transistor of PNP type having its base coupled to a first one of the two power electrodes of the power switch, its emitter coupled to a second one of the two power electrodes of the power switch, and its collector coupled to the control input of the starting circuit, and a second bipolar transistor of NPN type having its base coupled to the base of the first bipolar transistor, its emitter coupled to the collector of the first bipolar transistor, and its collector coupled to the emitter of the first bipolar transistor.

According to a particular embodiment, the starting circuit includes a third bipolar transistor having its base coupled to the emitter of the first bipolar transistor and to the collector of the second bipolar transistor, its emitter coupled to the collector of the first bipolar transistor, and its collector coupled to the control electrode of the power switch, or a MOSFET having its gate coupled to the emitter of the first bipolar transistor and to the collector of the second bipolar transistor, a first source or drain electrode coupled to the collector of the first bipolar transistor, and a second source or drain electrode coupled to the control electrode of the power switch.

According to a particular embodiment, the control device further includes at least one first current-limiting electric resistor coupled between the first one of the two power electrodes of the power switch and the sensing circuit.

According to a particular embodiment, the control device further includes an electric capacitance, coupled between the control input of the starting circuit and the second power electrode of the power switch.

According to a particular embodiment, the control device further includes a connection circuit configured to connect or not the sensing circuit to the first power electrode of the power switch.

According to a particular embodiment, the control device further includes at least one second current-limiting electric resistor coupled to the control input of the power switch.

According to a particular embodiment, the control device further includes a driver circuit comprising at least one output coupled to the control input of the starting circuit and comprising a galvanic insulation.

According to a particular embodiment, the driver circuit includes a microcontroller.

According to a particular embodiment, the driver circuit is configured to send on its output the starting control signal in the form of pulses clocked with zero-value crossing of a voltage across the power electrodes of the power switch.

It is also disclosed a power system comprising at least the power switch and a control device coupled to both power electrodes and to the control input of the power switch.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an example device for controlling at least one three-electrodes power switch according to a first embodiment;

FIG. 2, FIG. 3, FIG. 4, FIG. 5, and FIG. 6 illustrate example signals obtained using the control device shown in FIG. 1;

FIG. 7 illustrates electromagnetic noise obtained using the control device shown in FIG. 1;

FIGS. 8 and 9 illustrate example first and second alternatives of the control device according to the first embodiment, respectively;

FIG. 10 illustrates an example device for controlling at least one three-electrodes power switch according to a second embodiment;

FIG. 11 illustrates example signals obtained using the control device shown in FIG. 10;

FIG. 12 illustrates example signals obtained using a control device according to alternative embodiments;

FIG. 13 illustrates an example integration of the control device according to the second embodiment;

FIG. 14 illustrates an example of another alternative of the device for controlling at least one three-electrodes power switch according to the first embodiment;

FIG. 15 illustrates an example of another alternative of the device for controlling at least one three-electrodes power switch according to the second embodiment;

FIG. 16 illustrates examples of signals obtained using the control device of FIG. 14; and

FIG. 17 illustrates an example of another variant of the device for controlling at least one three-electrode power switch according to the first embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, different elements (transistors, pulse transformer, microcontroller, etc.) are not described in detail. Those skilled in the art will be able to perform these elements in detail based on the functional description of these elements hereinafter disclosed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. In addition, unless indicated otherwise, the words “coupled”, “linked” and “connected” are used to specify electrical coupling or links or connections.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures as orientated during normal use.

Unless specified otherwise, the expressions “around”, “approximately”, “substantially” and “in the order of” signify within 10%, and preferably within 5%.

Unless specified otherwise, value ranges here mentioned include the ends of these ranges.

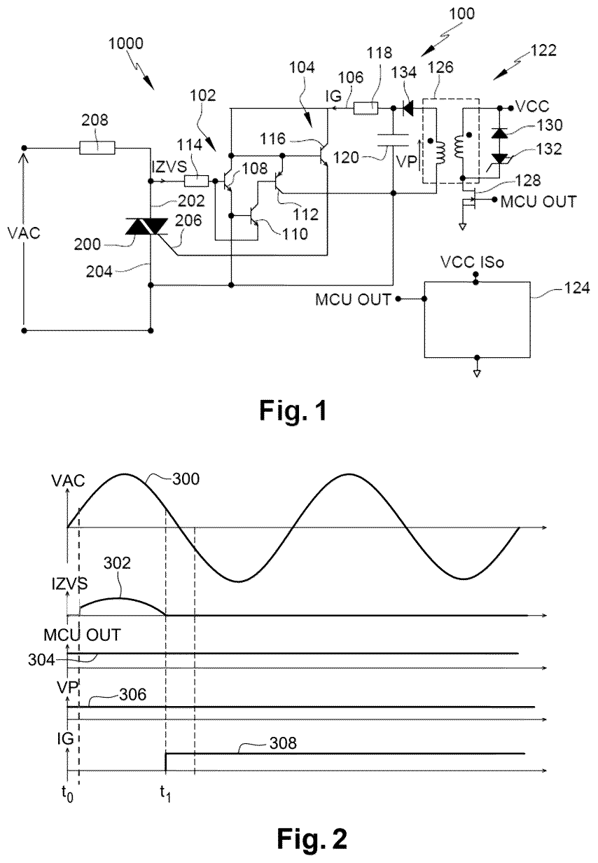

One example of a device 100 for controlling a three-electrodes power switch 200 according to a first embodiment is hereinafter described in relation to FIG. 1.

Power switch 200 comprises two power electrodes 202, 204 and one control electrode 206. In the example embodiment disclosed, the power switch 200 corresponds to a TRIAC, the power electrode 202 of which corresponds to the anode of the TRIAC, the power electrode 204 of which corresponds to the cathode of the TRIAC, and the control electrode 206 of which corresponds to the gate of the TRIAC. For example, device 100 could be configured to concurrently control one or more TRIACs and/or one or more thyristors (the power electrodes of which correspond to the anode and cathode of the thyristor, and the control electrode of which corresponds to the gate of the thyristor).

On the example shown in FIG. 1, TRIAC 200 is serially coupled to a resistive load 208 illustrated in FIG. 1 in the form of an electrical resistance. An AC voltage VAC is intended for being applied at the terminals of the assembly comprising the TRIAC 200 and the resistive load 208, i.e., between the electrode of the resistive load 208 being not coupled to the TRIAC 200 and the cathode 204 of the TRIAC 200 (the anode 202 of the TRIAC 200 being coupled to the resistive load 208). Alternatively, one or more other electric and/or electronic components of the power circuit to which the TRIAC 200 belongs could be coupled to the TRIAC 200. As an example, the value of the voltage VAC could be equal to 240 V_{RMS}, or more generally of between 85 V_{RMS} and 264 V_{RMS} in a single-phase network, or between 85 V_{RMS} and 460 V_{RMS} in a three-phase network, depending on the intended application.

Device 100 includes a sensing circuit 102 comprising bipolar transistors coupled to one of the two power electrodes 202, 204 of the TRIAC 200, and configured to extract a sensing current (current referred to as IZVS in FIG. 1), the value of which is proportional in particular to that of a voltage between the two electrodes 202, 204 when the TRIAC 200 is OFF. In the example embodiment described, the sensing circuit 102 extracts the sensing current IZVS from the anode 202 of the TRIAC 200.

Device 100 also includes a starting circuit 104 of the TRIAC 200, coupled to the gate 206 of TRIAC 200 and to the sensing circuit 102, and configured to supply a non-zero starting current on the gate 206 when the sensing current is zero and a non-zero starting control signal is received at a control input 106 of the starting circuit 104.

In the example embodiment disclosed, the sensing circuit 102 is configured to cause the sensing current IZVS flowing from one to another electrode 202, 204 of the TRIAC 200 when the TRIAC 200 is OFF.

In the example embodiment disclosed, the sensing circuit 102 includes at least: a first bipolar transistor 108 of NPN type having its base coupled to the anode 202 of the TRIAC 200, its collector coupled to the control input 106 of the starting circuit 104, and its emitter coupled to the cathode 204 of the TRIAC 200; a second bipolar transistor 110 of NPN type having its base coupled to the emitter of the first bipolar transistor 108, and its emitter coupled to the base of the first bipolar transistor 108; and a third bipolar transistor 112 of PNP type having its base coupled to the collector of the second bipolar transistor 110, its emitter coupled to the collector of the first bipolar transistor 108, and its collector coupled to the cathode 204 of the TRIAC 200.

In the example embodiment disclosed, device 100 further includes at least one first current-limiting electric resistor 114 coupled between the anode 202 of the TRIAC 200 and the sensing circuit 102. More particularly, in the example shown in FIG. 1, the first resistor 114 is coupled between the anode 202 of the TRIAC 200 and the base of the first bipolar transistor 108, and also between the anode of the TRIAC 200 and the emitter of the second bipolar transistor 110. This first resistor 114 allows the sensing current IZVS sent to the first and second bipolar transistors 108, 110 to be limited. The value of the IZVS detection current is also proportional to the value of the first resistor 114. The value of the first resistor 114 is, for example, equal to 500 kOhms, or more generally of between 250 kOhms and 2 MOhms, depending on the intended application.

In the example embodiment disclosed, starting circuit 104 includes a fourth bipolar transistor 116 of NPN type having its base coupled to the collector of the first bipolar transistor 108 (and also to the emitter of the third bipolar transistor 112), its collector coupled to the control input 106 (and also to the collector of the first bipolar transistor 108, to the emitter of the third bipolar transistor 112, and to its own base), and its emitter coupled to the gate 206 of the TRIAC 200.

In the example embodiment disclosed, device 100 further includes at least one second current-limiting electric resistor 118 coupled to the control input 106 in order to limit the current in the gate 206 of the TRIAC 200. In the example shown in FIG. 1, the second resistor 118 includes a first of its electrodes coupled to the collector of the first bipolar transistor 108, to the emitter of the third bipolar transistor 112, and to a collector, and to the base of the fourth bipolar transistor 116. The second resistor 118 here allows the starting current intended to be sent to the gate 206 of the TRIAC 200 through the fourth bipolar transistor 116 to be limited. The value of the second resistor 118 is, for example, equal to 56 Ohms, or more generally of between 20 Ohms and 15 kOhms, depending on the intended application.

In the example embodiment disclosed, device 100 further includes an electric capacitance 120, for example formed by a capacitor, coupled between the control input 106 and the cathode 204 of the TRIAC 200. In the example shown in FIG. 1, the electric capacitance 120 is coupled between a second electrode of the electric resistor 118 and the collector of the third bipolar transistor 112 which is in turn coupled to the cathode 204 of the TRIAC 200. The value of the electric capacitance 120 is of between 33 nF and 10 μF, depending on the intended application.

In the example embodiment disclosed, device 100 further includes a driver circuit 122 equipped with at least one output coupled to the control input 106, and galvanically insulated from other elements of the driver circuit 122. According to a specific embodiment, corresponding to that illustrated in FIG. 1, the driver circuit 122 includes a microcontroller 124.

In the example shown in FIG. 1, the driver circuit 122 further includes a pulse transformer 126 equipped with a primary coupled to a MOSFET transistor 128, the gate of which is coupled to an output of the microcontroller 124 on which a starting control signal “MCU-OUT” is output. In the example shown in FIG. 1, the MOSFET transistor 128 is of N type, and includes its drain coupled to one of the ends of the primary winding of the pulse transformer 126, and its source coupled to a reference electric potential such as the ground of the driver circuit 122. As an alternative, the transistor 128 may be a bipolar transistor. In the example shown in FIG. 1, the driver circuit 122 also includes a diode 130 and a Zener diode 132 forming an assembly parallelly coupled to the primary of the pulse transformer 126. The secondary of the pulse transformer 126 is parallelly coupled to the electric capacitance 120 through another diode 134. As an example, the value of the current output from the driver circuit 122 is, for example, equal to around 65 mA, or more generally of between 1 mA and 200 mA.

In the example shown, diodes 130, 132 and 134 enable to demagnetize the magnetic circuit of the pulse transformer 126 each time transistor 128 is opened.

The device 100 according to the first embodiment allows a starting of the TRIAC 200 to be controlled in the quadrants Q1 and Q4, i.e., by applying a positive starting current on the gate 206 of the TRIAC 200, and with a voltage across the TRIAC 200 being positive (Q1) or negative (Q4).

When the TRIAC 200 is OFF, the first, second, and third bipolar transistors 108, 110 and 112 cause the sensing current IZVS to flow from one to another electrodes 202, 204 of the TRIAC 200. Switching these transistors 108, 110, and 112 occurs when this current crosses a zero value, which allows automatically detecting when these crossing occur thanks to these switching. Given that the value of this current is proportional to the value of the voltage across the TRIAC 200 when the TRIAC 200 is OFF, the switching of the transistors 108, 110, 112 allows the zero-value crossing of the voltage across the TRIAC 200 to be sensed. More specifically, when the voltage between the electrodes 202, 204 of the TRIAC 200 is positive, the sensing current IZVS flows from the anode 202 to the cathode 204 of the TRIAC 200 through the first bipolar transistor 108. When the voltage between the electrodes 202, 204 of the TRIAC 200 is negative, the sensing current IZVS flows from the cathode 204 to the anode 202 of the TRIAC 200 through the second bipolar transistor 110. The third bipolar transistor 112 enables to divert the base current of the fourth bipolar transistor 116, since the third bipolar transistor 112 is controlled by the second bipolar transistor 110 and to avoid activating the fourth bipolar transistor 116 and supplying current to the gate 206 of the TRIAC 200 when the IZVS current is non-zero.

In this first embodiment, the fourth bipolar transistor 116 operates as a control transistor supplying a positive non-zero starting current on the gate of the TRIAC 200 when the sensing current IZVS is zero and a non-zero starting control signal is received on the control input 106. In the example shown in FIG. 1, the starting current is supplied by the electric capacitance 120 that the pulse transformer 126 pre-charged.

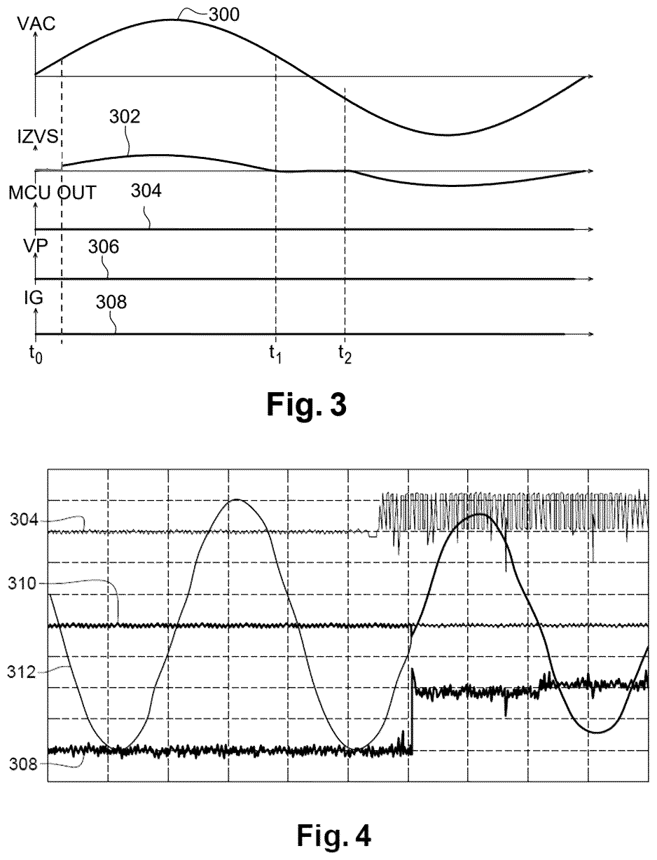

FIG. 2 illustrates example signals obtained in the device 100 according to the first embodiment and as previously described in relation to FIG. 1 during a starting of the TRIAC 200. In FIG. 2, reference 300 designates the AC voltage VAC applied across the assembly formed by the TRIAC 200 and the resistive load 208, reference 302 designates the sensing current IZVS extracted by the sensing circuit 102, the reference 304 designates the starting control signal MCU OUT sent by the microcontroller 124 on the gate of the MOSFET transistor 128, the reference 306 designates the voltage VP obtained across the primary of the pulse transformer 126, and the reference 308 designates the starting current IG received on the gate 206 of the TRIAC 200. In the example embodiment, the starting control signal MCU OUT corresponds to a modulated current PWM (Pulse Width Modulation) the DC value of which is, for example, equal to 3.3 V, or more generally of between 3 V and 5 V. In addition, the starting current IG sent in the gate 206 is, for example, in the order of a hundred milliamperes, or more generally of between 200 μA and 200 mA.

In FIG. 2, between times t0 and t1, the voltage VAC is positive, and the value of the sensing current IZVS varies proportionally to that of voltage VAC. Between times t0 and t1, the first bipolar transistor 108 is ON, and other bipolar transistors 110, 112, and 116 are OFF. Although the starting control signal MCU OUT is non-zero between these times, the starting current IG remains zero given the fact that the fourth bipolar transistor 116 is OFF. At time t1, the voltage across TRIAC 200 is zero and the sensing current IZVS is also zero. The first bipolar transistor 108 then turns OFF, the second and third bipolar transistors 110, 112 remaining OFF. However, the fourth bipolar transistor 116 turns ON. Given the non-zero starting control signal MCU OUT sent to the microcontroller 124 of the driver circuit 122, the voltage VP across the secondary of the pulse transformer 126 is not zero. Turning the fourth bipolar transistor 116 ON then causes a non-zero starting current IG to be sent in the gate 206 of the TRIAC 200, triggering its starting. As an example, the value of the starting current IG allowing the starting of the TRIAC 200 to be triggered could be equal to around 29 mA, or more generally of between 200 μA and 200 mA, depending on the properties of the TRIAC 200.

FIG. 3 illustrates example signals obtained in the device 100 according to the first embodiment and as previously described in relation to FIG. 1 when the TRIAC 200 is kept OFF, when the MOSFET 128 is not controlled.

In FIG. 3, between times t0 and t1, the voltage VAC is positive, and the value of the sensing current IZVS varies proportionally to that of voltage VAC. In addition, between times t0 and t1, the first bipolar transistor 108 is ON, and other bipolar transistors 110, 112, and 116 are OFF.

Between times t1 and t2, the sensing current IZVS is zero. The first bipolar transistor 108 turns OFF, and the fourth bipolar transistor 116 then turns ON. The second and third bipolar transistors 110, 112 remain OFF. Given the fact that the starting control signal MCU OUT is zero between these times t1 and t2, the starting current IG remains zero, and the TRIAC 200 remains OFF.

After time t2, the voltage VAC is negative, and the value of the sensing current IZVS varies proportionally to that of voltage VAC. The second and third bipolar transistors 110, 112 are ON, and other bipolar transistors 108, 116 are OFF. The fourth bipolar transistor 116 turns ON as soon as the first bipolar transistor 108 is OFF (when the VAC voltage is positive) or as soon as the second and third bipolar transistors 110, 112 are OFF (when the VAC voltage is negative).

FIG. 4 illustrates example signals obtained in the device 100 according to the first embodiment and as previously described in relation to FIG. 1 when the TRIAC 200 is starting. In FIG. 4, the current IAC designated by reference 310 corresponds to the current flowing through the TRIAC 200, and reference 312 designates the voltage VAK obtained across the TRIAC 200. Further, as in FIGS. 2 and 3, reference 304 designates the starting control signal MCU OUT (referred to as EN in FIG. 4) sent by the microcontroller 124 on the gate of the MOSFET transistor 128, and reference 308 designates the starting current IG received on the gate 206 of the TRIAC 200. In this FIG. 4, when the value of signal MCU OUT is no more zero, and so that it controls the starting of the TRIAC 200, the latter starts as soon as the voltage VAK is zero, which causes the fourth bipolar transistor 116 to turn ON, and the starting current IG to be sent on the gate 206. An AC current IAC then flows through the TRIAC 200. The VAC voltage applied on terminals of the TRIAC 200 becomes zero as soon as the TRIAC 200 becomes ON. In this case, this voltage is thus only applied on the load 208.

FIG. 5 illustrates example signals obtained in the device 100 according to the first embodiment and as previously described in relation to FIG. 1 when the TRIAC 200 is turning OFF. The signals illustrated in FIG. 5 correspond to those previously described in relation to FIG. 4. In this FIG. 5, when the starting control signal MCU OUT goes zero and controls the turning OFF of the TRIAC 200, the latter turns OFF as soon as the current IAC goes again to a zero value and that the current IG received at its gate 206 is zero. As soon as the TRIAC 200 turns OFF, the voltage VAK across the TRIAC 200 appears again, and the current IAC remains zero.

As an alternative of the example embodiment of device 100 previously described, the driver circuit 122 could differ from that illustrated in FIG. 1, and could correspond to any type of driver circuit allowing an electrically-insulated control of one or more three-electrodes power switches. FIG. 6 illustrates example signals obtained in the device 100 according to the first embodiment and as previously described in relation to FIG. 1 during a starting of the TRIAC 200, with however a driver circuit 122 different from that previously described and which corresponds to a DC/DC converter insulated with a converter type insulation.

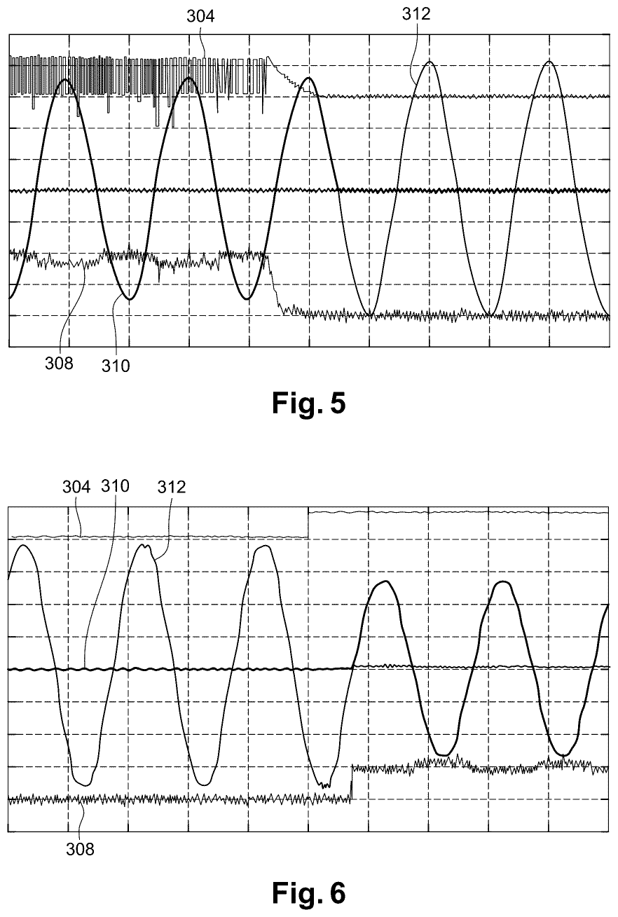

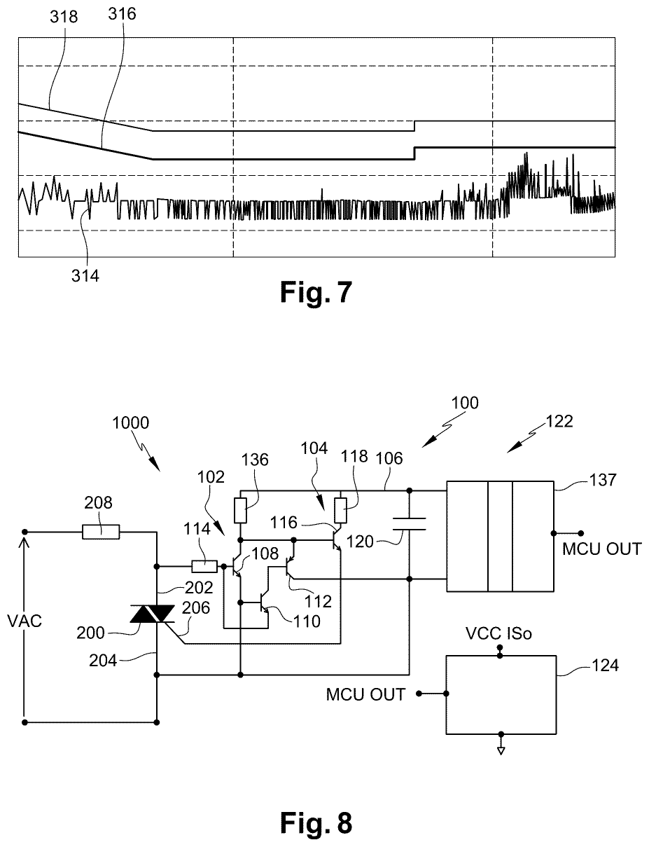

Curve 314 illustrated in FIG. 7 represents the electromagnetic noise of the device 100 measured at different frequencies, and which corresponds to a Fourier series decomposition of the IAC current. Reference 316 designates the maximum mean value allowed according to the standard NF EN IEC 55014-1, and the reference 318 designates the maximum quasi-peak allowed according to this standard. Curve 314 emphasizes that, whatever the value of the considered frequency, the electromagnetic noise obtained in the device 100 remains compliant with the requirements of the standard NF EN IEC 55014-1.

In the example embodiment previously disclosed, the second electric resistor 118 coupled to the control input 106 includes a first of its electrodes coupled to the collector of the first bipolar transistor 108, to the emitter of the third bipolar transistor 112, and to the collector of the fourth bipolar transistor 116, an a second of its electrodes coupled to one of the electrodes of the electric capacitance 120.

In a first alternative embodiment of the device 100 illustrated in FIG. 8, the first electrode of the second electric resistor 118 is coupled to the collector of the fourth bipolar transistor 116, and its second electrode is coupled to one of the electrodes of the electric capacitance 120. In this first alternative, the device 100 further includes a third current-limiting electric resistor 136 having a first electrode coupled to the collector of the first bipolar transistor 108, to the emitter of the third bipolar transistor 112 and to the base of the fourth bipolar transistor 116, and a second electrode coupled to the second electrode of the second electric resistor 118 and to the electric capacitance 120. This third electric resistor 136 allows the current sent to the first and third bipolar transistors 108, 112 to be limited, and particularly allows the power consumption of the device 100 to be reduced when these transistors are ON. For example, the value of the third electric resistor 136 is higher than, or equal to, sensibly 1 kOhms. Further, in this first alternative, the assembly formed by the pulse transformer 126, the MOS transistor 128, and the diodes 130, 132, 134 is replaced with a single circuit 137 having particularly a galvanic insulation between a part performing the receipt of the starting control signal MCU OUT and another part coupled to the electric capacitance 120 and used to send the starting current IG.

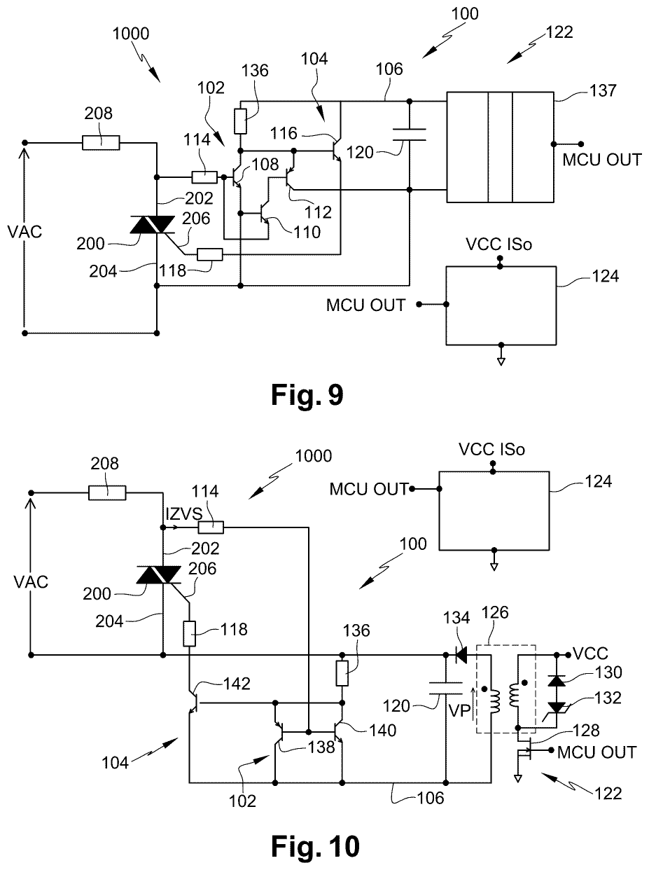

In a second alternative embodiment of the device 100 illustrated in FIG. 9, the device 100 includes the third electrical resistor 136 coupled as in the first alternative previously described. However, the second electrical resistor 118 is herein coupled between the gate 206 of the TRIAC 200, and the emitter of the fourth bipolar transistor 116.

Generally speaking, the configuration previously described in connection with FIG. 1 reduces the number of electrical resistors to be coupled to device 100. The configuration previously described in connection with FIG. 3 make it possible to integrate the assembly and place a resistor outside the device 100 to regulate the IG activating current.

An example device 100 according to a second embodiment is hereinafter described in relation to FIG. 10.

In this second embodiment, the sensing circuit 102 includes at least: a first bipolar transistor 138 of PNP type having its base coupled to the anode 202 of the TRIAC 200 via the first electric resistor 114, its emitter coupled to the cathode 204 of the TRIAC 200 via the third electric resistor 136, and its collector coupled to the control input 106 of the starting circuit 104, and a second bipolar transistor 140 of NPN type having its base coupled to the base of the first bipolar transistor 138, its emitter coupled to the collector of the first bipolar transistor 138, and its collector coupled to the emitter of the first bipolar transistor 138.

In the example embodiment described, the starting circuit 104 includes a third bipolar transistor 142 having its base coupled to the emitter of the first bipolar transistor 138 and to the collector of the second bipolar transistor 140, its emitter coupled to the collector of the first bipolar transistor 138 and to the emitter of the second bipolar transistor 140, and its collector coupled to the gate 206 of the TRIAC 200 via the second electric resistor 118.

This second embodiment of the device 100 allows a starting of the TRIAC 200 to be controlled in the quadrants Q2 and Q3, i.e., by applying a negative starting current on the gate 206 of the TRIAC 200 and with a voltage across the TRIAC 200 being either positive (Q2), or negative (Q3).

When the TRIAC 200 is OFF, the first and second bipolar transistors 138, 140 cause the sensing current IZVS to flow from one to another electrodes 202, 204 of the TRIAC 200. Switching these transistors 138, 140 occurs upon zero value crossing of this sensing current IZVS, which allows automatically sensing when these crossing occur thanks to sensing these switching. More particularly, when the voltage between the electrodes 202, 204 of the TRIAC 200 is positive, the sensing current IZVS flows from the anode 202 to the cathode 204 of the TRIAC 200 through the second bipolar transistor 140. When the voltage between the electrodes 202, 204 of the TRIAC 200 is negative, the sensing current IZVS coming from the neutral of the VAC voltage flows through the first bipolar transistor 138.

The third bipolar transistor 142 operates as a control transistor supplying a negative non-zero starting current coming from the gate 206 of the TRIAC 200 when the sensing current IZVS is zero, and when the voltage across the TRIAC 200 is thus zero, and when a non-zero starting control signal is received on the control input 106. In the example shown in FIG. 1, the starting current is supplied by the electric capacitance 120 pre-charged by the pulse transformer 126 and enables to control the TRIAC 200 in the quadrants Q2 and Q3.

As an alternative to the second embodiment of the device 100 previously described, the driver circuit 122 could differ from that illustrated in FIG. 10, and could correspond to any type of driver circuit allowing an electrically insulated control of one or more three-electrodes power switches.

FIG. 11 illustrates example signals obtained in the device 100 previously disclosed in relation to FIG. 10 during a starting of the TRIAC 200. In FIG. 11, reference 300 designates the AC voltage VAC applied across the assembly formed by the TRIAC 200 and the resistive load 208, the reference 304 designates the starting control signal, referred to as EN, sent by the microcontroller 124 to control the TRIAC 200, the reference 308 designates the starting current IG received on the gate 206 of the TRIAC 200, and the reference 310 designates the current IAC flowing through the TRIAC 200.

In FIG. 11, between times t0 and t1, the alternative voltage VAC pass through positive, negative, and zero values. From time t1, signal EN goes non zero, and has a value controlling the starting of the TRIAC 200. At the time t2, corresponding to the first crossing through a zero value by the voltage VAC from the time t1, the TRIAC 200 turns ON thanks to the negative starting circuit received on the gate 206. The current IAC thus varies proportionally to the voltage VAC.

In an alternative embodiment applicable to the first and second embodiments, the device 100 could further include or not an interconnection element configured to connect the sensing circuit 102 to the first power electrode of the power switch, i.e., to the anode 202 of the TRIAC 200 in the previously described examples. For example, this interconnection element could correspond to a switch interposed between the first electric resistor 114 and the anode 202 of the TRIAC 200. When the sensing circuit 102 is disconnected from the anode 202 of the TRIAC 200, The starting of the TRIAC 200 launches as soon as the non-zero starting current is received on its gate 206, whatever the value of voltage VAC. In this alternative, when the sensing circuit 102 is disconnected from the TRIAC 200, starting the TRIAC 200 could be launched whatever the value of voltage VAC.

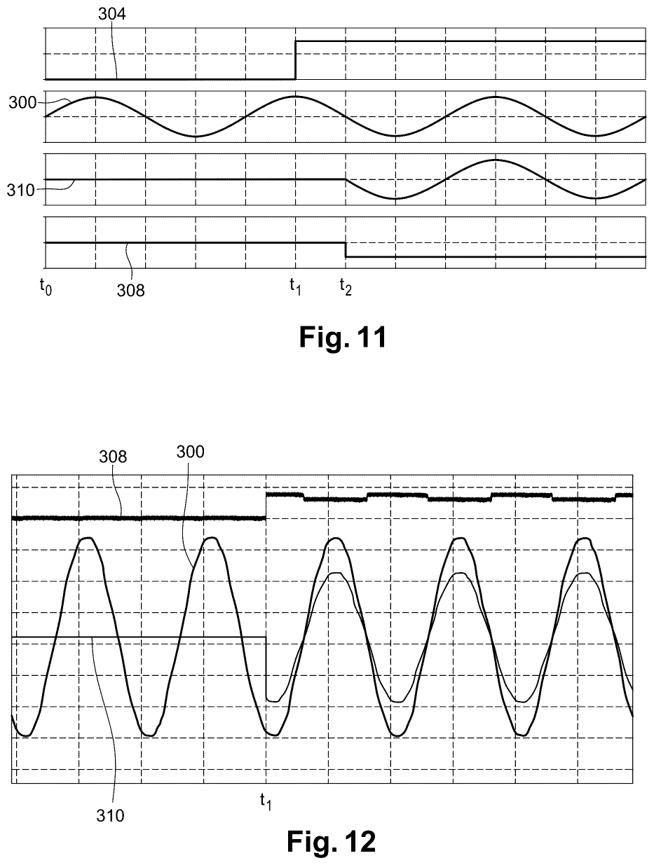

FIG. 12 illustrates example signals obtained in a device 100 according to this alternative. The references used to designate the signals illustrated on this drawing are similar to those used in the previous drawings. In the example shown in FIG. 12, at time t1, the non-zero starting current IG is sent on the gate 206 of the TRIAC 200. As from this time point, the TRIAC 200 starts and turns ON whatever the value of voltage VAC.

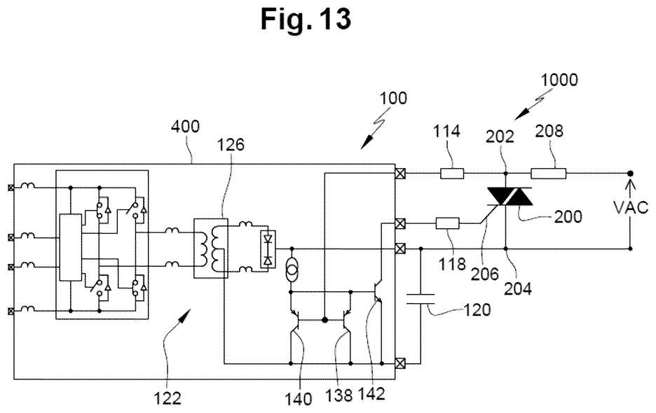

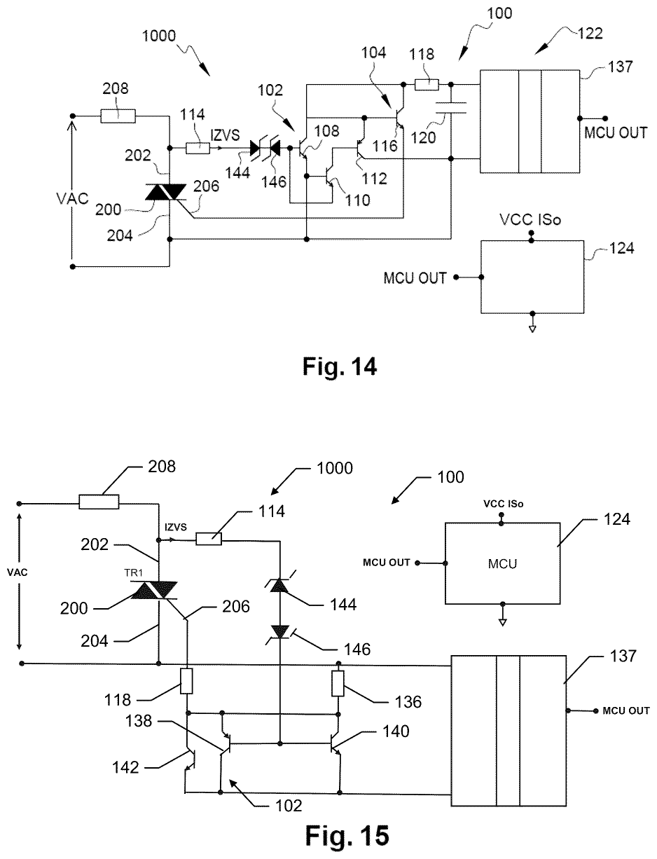

FIG. 13 illustrates an example embodiment of the device 100 in the form of an integrated circuit 400. In this example, the device 100 is implemented according to the second embodiment. Different components for controlling the integrated circuit 400 used to generate the starting control signal are illustrated in FIG. 14, but are not described in detail here. The first and second resistors 114, 118 and the electric capacitance 120 are not integrated within the integrated circuit 400, but correspond to outer components connected to inputs/outputs of the integrated circuit 400. Alternatively, the electric capacitance 120 could be integrated within the integrated circuit 400.

The different alternatives previously disclosed could apply to the device 100 so implemented.

In all examples and embodiments previously disclosed, the starting circuit 104 includes a bipolar transistor (the fourth bipolar transistor 116 in the first embodiment, or the third bipolar transistor 142 in the second embodiment) forming a switch allowing the starting current to the gate 206 of the TRIAC 200 to be supplied. Alternatively, the starting circuit 104 could include a MOS transistor instead of the fourth bipolar transistor 116 or the third bipolar transistor 142. In this alternative, the gate of the MOS transistor is connected as the base of the bipolar transistor 116 or 142, and the drain and source electrodes are analog-connected to the emitter and to the collector of the bipolar transistor 116 or 142.

As an alternative to the previously described embodiments, the device 100 may also include two Zener diodes 144, 146 for adjusting the conduction time of the transistors.

FIG. 14 shows the device 100 according to the first embodiment and comprising the two Zener diodes 144, 146 coupled in series with each other and such that their cathodes are coupled to each other. The anode of Zener diode 144 is coupled to the first resistor 114, and the anode of Zener diode 146 is coupled to the base of the first bipolar transistor 108. The other elements of device 100 are similar to those previously described.

FIG. 15 shows the device 100 according to the second embodiment and comprising the two Zener diodes 144, 146 coupled in series with each other and such that the cathode of the Zener diode 146 is coupled to the anode of the Zener diode 144. The cathode of Zener diode 144 is coupled to the base of first bipolar transistor 138, and the anode of Zener diode 146 is coupled to the base of second bipolar transistor 140.

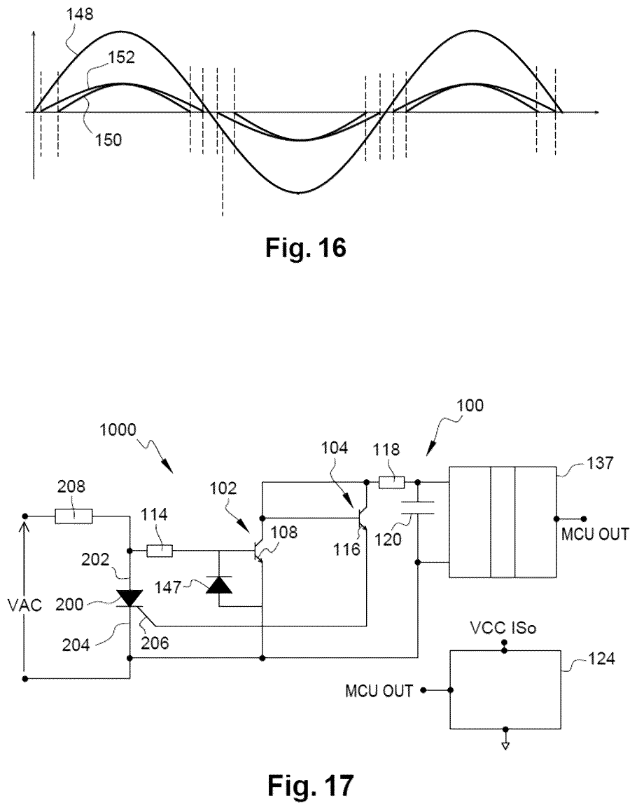

FIG. 16 shows, for a VAC voltage designated by reference 148, an IZVS current, designated by reference 150, obtained in the device 100 of the FIG. 14. By way of comparison, reference 152 denotes the IZVS current obtained in device 100 in the absence of Zener diodes 144, 146. These curves show that the presence of Zener diodes 144, 146 in device 100 makes it possible to modify the instants at which the bipolar transistors coupled to these Zener diodes change from one state, ON or OFF, to the other.

These Zener diodes 144, 146 may also be present in the other previously described variants of the device 100.

According to another variant shown in FIG. 17, the power switch 200 corresponds to a thyristor. Furthermore, in this variant, the device 100 comprises, as bipolar transistor, only the first bipolar transistor 108 and the fourth bipolar transistor 116. In this variant, the device 100 also comprises a diode 147 having its cathode coupled to the first resistor 114 and to the base of the first bipolar transistor 108, and its anode coupled to the emitter of the first bipolar transistor 108. This variant can be combined with the other previously described variants, for the different described embodiments.

In the different configurations, examples and embodiments, device 100 allows at least one three-electrodes power switch as a TRIAC or a thyristor to be automatically controlled, and allowing the starting or turning OFF the power switch to be automatically controlled upon a zero-crossing of an AC voltage applied on the power switch without sensing this zero-crossing being sensed with a microcontroller.

In addition, the device 100 does not require adding an outer circuit parallelly coupled to the power switch to sense the zero crossing of the power AC voltage received by the device 100.

Further, the device 100 causes no long delay between the starting control received by the device 100 and the starting of the power switch.

The device 100 also allows to have the advantages brought by a ZVS control of the power switch while causing few electromagnetic disturbances.

Depending to the selected embodiment, the device 100 could perform starting the power switch in any quadrants Q1, Q2, Q3, and Q4.

In the different configurations, examples and embodiments, reference 1000 designates the power system including the power switch 200, the power circuit the switch 200 is coupled to, as well as the control device 100.

The device 100 could be used in numerous fields using such power systems 1000 as electric vehicle field, industry field, power converter field, domestic household and working appliance field, etc.

The device 100 is, for example, intended for the automotive industry. Electrifying motor vehicles causes an increasingly high level of electronic content in vehicles. The device 100 could be used within systems comprising, for example, thyristors, TRIACs, rectifiers, high voltage transient voltage protection diodes, modules, etc. intended to be integrated within said vehicles. Driving automation also causes an electronic content increasingly high within vehicles. Such systems comprise, for example, high voltage transient voltage protection diodes, an electromagnetic discharge protection, and common mode filters to protect against electric hazards within the emerging complex electronics.

The device 100 could, for example, be used in the industry field. More particularly, the device 100 could, for example, be used in developing green energies, or infrastructure electrification, for example for charge stations or in integrating solar energy. The device 100 could also be used in the fields of Internet of Things or smart home. For example, the device 100 is intended to be implemented in circuits supplying power to equipment, for example including 800 V or 1200 V thyristors, 1200 V ultrafast silicon carbide diodes, transient voltage suppression diodes, and electromagnetic discharge protections. The device 100 could also be used to implement cloud, 5G networks, datacenters, and servers.

For example, the device 100 is intended to be used in communications equipment, or in computers and peripherals. For example, the device 100 could be used in 5G infrastructures and dedicated datacenters. For example, the device 100 could be part of equipment comprising silicon carbide diodes, Schottky power transistors, electromagnetic discharge protection, and transient voltage suppression diodes. The device 100 could also be used in satellites comprising, for example, integrated passive devices for RF applications.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A control device of at least one power switch with three-electrodes, comprising at least:
a sensing circuit comprising bipolar transistors coupled to a first power electrode of the power switch, and configured to extract a sensing current, a value of which is proportional to that of a voltage between the first power electrode and a second power electrode of the power switch when the power switch is OFF; and
a starting circuit, coupled to a control electrode of the power switch and to the sensing circuit, and configured to supply a non-zero starting current on the control electrode when the sensing current is zero and a non-zero starting control signal is received at a control input of the starting circuit.

2. The control device according to claim 1, wherein the sensing circuit is configured to cause the sensing current flowing from one to the another first and a second electrodes of the power switch when the power switch is OFF.

3. The control device according to claim 1, configured to control the power switch corresponding to a TRIAC, the control electrode corresponding to a gate of the TRIAC, and the first and second power electrodes corresponding to anodes of the TRIAC.

4. The control device according to claim 1, wherein the bipolar transistors of the sensing circuit correspond at least to:
a first bipolar transistor of NPN type having its base coupled to the first power electrode of the power switch, its collector coupled to the control input of the starting circuit, and its emitter coupled to the second power electrode of the power switch;
a second bipolar transistor of NPN type having its base coupled to the emitter of the first bipolar transistor, and its emitter coupled to the base of the first bipolar transistor; and
a third bipolar transistor of PNP type having its base coupled to the collector of the second bipolar transistor, its emitter coupled to the collector of the first bipolar transistor, and its collector coupled to the second power electrode of the power switch.

5. The control device according to claim 4, wherein the starting circuit includes a fourth bipolar transistor of NPN type having its base coupled to the collector of the first bipolar transistor, its collector coupled to the control input of the starting circuit, and its emitter coupled to the control electrode of the power switch, or a MOSFET transistor having its gate coupled to collector of the first bipolar transistor, a first source or drain electrode coupled to the control input of the starting circuit, and a second source or drain electrode coupled to the control electrode of the power switch.

6. The control device according to claim 1, wherein the bipolar transistors of the sensing circuit correspond at least to:
a first bipolar transistor of PNP type having its base coupled to a first one of the first and second power electrodes of the power switch, its emitter coupled to a second one of the first and second power electrodes of the power switch, and its collector coupled to the control input of the starting circuit; and
a second bipolar transistor of NPN type having its base coupled to the base of the first bipolar transistor, its emitter coupled to the collector of the first bipolar transistor, and its collector coupled to the emitter of the first bipolar transistor.

7. The control device according to claim 6, wherein the starting circuit includes a third bipolar transistor having its base coupled to the emitter of the first bipolar transistor and to the collector of the second bipolar transistor, its emitter coupled to the collector of the first bipolar transistor, and its collector coupled to the control electrode of the power switch, or a MOSFET having its gate coupled to the emitter of the first bipolar transistor and to the collector of the second bipolar transistor, a first source or drain electrode coupled to the collector of the first bipolar transistor, and a second source or drain electrode coupled to the control electrode of the power switch.

8. The control device according to claim 1, further including at least one first current-limiting electric resistor coupled between the first one of the first and second power electrodes of the power switch and the sensing circuit.

9. The control device according to claim 1, further including an electric capacitance, coupled between the control input of the starting circuit and the second power electrode of the power switch.

10. The control device according to claim 1, further including a connection circuit configured to connect or not the sensing circuit to the first power electrode of the power switch.

11. The control device according to claim 1, further including at least one second current-limiting electric resistor coupled to the control input of the power switch.

12. The control device according to claim 1, further including a driver circuit comprising at least one output coupled to the control input of the starting circuit (104) and comprising a galvanic insulation.

13. The control device according to claim 12, wherein the driver circuit includes a microcontroller.

14. The control device according to claim 12, wherein the driver circuit is configured to send on its output the starting control signal in the form of pulses clocked with zero-value crossing of a voltage across the power electrodes of the power switch.

15. A power system comprising:
at least one power switch with three-electrodes; and
a control device coupled to both power electrodes and to a control input of the at least one power switch, wherein the control device comprises:
a sensing circuit comprising bipolar transistors coupled to a first power electrode of the power switch, and configured to extract a sensing current, a value of which is proportional to that of a voltage between the first power electrode and a second power electrode of the power switch when the power switch is OFF; and
a starting circuit, coupled to a control electrode of the power switch and to the sensing circuit, and configured to supply a non-zero starting current on the control electrode when the sensing current is zero and a non-zero starting control signal is received at a control input of the starting circuit.

16. The power system according to claim 15, wherein the sensing circuit is configured to cause the sensing current flowing from one to the another first and a second electrodes of the power switch when the power switch is OFF.

17. The power system according to claim 15, wherein the bipolar transistors of the sensing circuit correspond at least to:
a first bipolar transistor of NPN type having its base coupled to the first power electrode of the power switch, its collector coupled to the control input of the starting circuit, and its emitter coupled to the second power electrode of the power switch;
a second bipolar transistor of NPN type having its base coupled to the emitter of the first bipolar transistor, and its emitter coupled to the base of the first bipolar transistor; and
a third bipolar transistor of PNP type having its base coupled to the collector of the second bipolar transistor, its emitter coupled to the collector of the first bipolar transistor, and its collector coupled to the second power electrode of the power switch.

18. The power system according to claim 17, wherein the starting circuit includes a fourth bipolar transistor of NPN type having its base coupled to the collector of the first bipolar transistor, its collector coupled to the control input of the starting circuit, and its emitter coupled to the control electrode of the power switch, or a MOSFET transistor having its gate coupled to collector of the first bipolar transistor, a first source or drain electrode coupled to the control input of the starting circuit, and a second source or drain electrode coupled to the control electrode of the power switch.

19. The power system according to claim 15, wherein the bipolar transistors of the sensing circuit correspond at least to:
a first bipolar transistor of PNP type having its base coupled to a first one of the first and second power electrodes of the power switch, its emitter coupled to a second one of the first and second power electrodes of the power switch, and its collector coupled to the control input of the starting circuit; and
a second bipolar transistor of NPN type having its base coupled to the base of the first bipolar transistor, its emitter coupled to the collector of the first bipolar transistor, and its collector coupled to the emitter of the first bipolar transistor.

20. The power system according to claim 19, wherein the starting circuit includes a third bipolar transistor having its base coupled to the emitter of the first bipolar transistor and to the collector of the second bipolar transistor, its emitter coupled to the collector of the first bipolar transistor, and its collector coupled to the control electrode of the power switch, or a MOSFET having its gate coupled to the emitter of the first bipolar transistor and to the collector of the second bipolar transistor, a first source or drain electrode coupled to the collector of the first bipolar transistor, and a second source or drain electrode coupled to the control electrode of the power switch.
